(19) United States
(12) Patent Application Publication
(10) Pub. No.: US 2002/0079570 A1
(43) Pub. Date: Jun. 27, 2002

(54) Semiconductor package with heat dissipating element

(75) Inventors: Tzong-Da Ho, Taichung (TW); Chien-Ping Huang, Hsinchu (TW); Yu-Po Wang, Miaoli (TW)

Correspondence Address: MR. PETER F. CORLESS, EDWARDS & ANGELL, LLP, 101 FEDERAL STREET, BOSTON, MA, 02110, US

(73) Assignee: Siliconware Precision Industries Co., Ltd,

(21) Appl. No.: 09/924,049

(22) Filed: Aug. 7, 2001

(30) Foreign Application Priority Data
Dec. 26, 2000 (TW) 89127899

(51) Int. Cl. H01L 23/48

(52) U.S. Cl. 257/697

(57) ABSTRACT

A semiconductor package with a heat dissipating element is proposed, in which the contact area between a semiconductor chip and the heat dissipating element is significantly reduced as the chip merely has its edge portion attached to the dissipating element. This makes an effect of a thermal stress on the chip reduced so as to prevent cracking and delamination for the chip. Moreover, the chip is partially exposed to the atmosphere, which allows the efficiency of heat dissipation and moisture escapement to be improved, so as to prevent a popcorn effect from occurrence and make the semiconductor package assured in reliability and quality.

### FIELD OF THE INVENTION

The present invention relates to semiconductor packages, and more particularly, to a semiconductor package with a heat dissipating element so as to improve the heat dissipating efficiency.

### BACKGROUND OF INVENTION

A BGA (ball grid array) semiconductor package is a mainstream package product due to provision of sufficient I/O connections for a semiconductor chip with high density of electronic elements and electronic circuits. However, as the electronic elements and electronic circuits are disposed on the chip in high density, a large amount of heat is accordingly generated, whereas if the heat can not be effectively dissipated, the performance and lifetime of the semiconductor chip will be seriously deteriorated.

Conventionally, the semiconductor chip in the semiconductor package is encapsulated by an encapsulant, which is made of a molding resin poor in thermal conductivity for having a coefficient of thermal conductivity (K) of approximately 0.8 w/m° K. Moreover, the chip has a coefficient of thermal expansion (CTE) of approximately 3 ppm/° C., which is much different from the molding resin with a CTE of approximately 20 ppm/° C. Thus, after forming the encapsulant for encapsulating the chip, in a curing process for solidifying the encapsulant, a solder reflow process for bonding the semiconductor package to a printed circuit board and a reliability test for the semiconductor package during a temperature cycle, thermal expansion and shrinkage of the encapsulant generated in a great temperature variation will cause a thermal stress to the chip and thus lead to breakage or cracking for the chip.

In order to improve the heat dissipation for the conventional semiconductor package, a semiconductor package with a heat sink is disclosed accordingly) in which the heat sink is mounted on a semiconductor chip and then together with the chip are encapsulated by an encapsulant. However, although the provision of the heat sink helps for the heat dissipation, a long thermally conductive path makes the heat generated by the chip pass through the chip, the encapsulant poor in thermal conductivity and the heat sink to be dissipated to the atmosphere. As a result, the overall heat dissipating efficiency still cannot be satisfactorily achieved.

Therefore, U.S. Pat. No. 5,420,460 teaches a low-profile semiconductor package in which a heat sink is exposed to outside of an encapsulant, so as to resolve the foregoing drawbacks and achieve the miniaturization in profile. As shown in FIG. 1, the semiconductor package employs a structure of thin cavity down ball grid array (TCDBGA), in which at the center of the heat sink there is formed a thin cavity with a downward opening for attaching an inactive surface of a semiconductor chip thereto by a thermally conductive adhesive, and then the chip is encapsulated by the encapsulant. This allows heat generated by the chip to pass quickly through the thermally conductive adhesive and the heat sink to be dissipated to the atmosphere without passing through the encapsulant, so that the heat dissipating efficiency can be improved.

However, in the foregoing semiconductor package, the semiconductor chip is firmly attached to a surface of the heat sink, and as mentioned above, the coefficient of thermal expansion (CTE) of the silicon semiconductor chip is approximately 3 ppm/° C., while heat sink generally made of copper has a CTE of 18 ppm/° C. Thus, a significant thermal stress will be generated by the beat sink to the semiconductor chip during a temperature cycle in operation of different processes. Moreover, as the semiconductor package is a low-profile device, warpage tends to occur in a substrate, which is not sufficient in plane support for overcoming the thermal stress. This further results in cracking for the semiconductor chip, and delamination between the chip and the heat sink and between the substrate and the heat sink as well as between the substrate layers. In addition, the warpage of the substrate not only reduces the planarity of the substrate but also detrimentally affects the bonding quality, making the package products deteriorated in quality and reliability.

Besides, in the foregoing U.S. Pat. No. 5,450,460, the semiconductor chip is entirely encapsulated within a hermetically sealed cavity formed by the heat sink and the encapsulant. Further, the encapsulant is made of a moisture absorbing material such as epoxy resin, while moisture tends to penetrate into the semiconductor package through gaps existing at an interface between the encapsulant and the heat sink or the semiconductor chip. Therefore, in operation of a surface mounting technology or a reflow process at a temperature between 210 and 260° C., he high temperature makes the moisture in the semiconductor package quickly evaporate, which induces significant increase in internal pressure for the package, and thus causes a popcorn effect or delamination at interfaces between elements in the semiconductor package.

### SUMMARY OF THE INVENTION

A primary objective of the present invention is to provide a semiconductor package with a heat dissipating element, in which a semiconductor chip is partially exposed to the atmosphere directly so as to reduce a thermal stress resulted from difference in coefficient of thermal expansion between the heat dissipating element and the semiconductor chip, and to prevent cracking for the semiconductor chip and delamination from occurrence, and thus planarity as well as bonding quality can be assured in the semiconductor package. Moreover, the semiconductor package of the invention allows moisture in the package to directly escape through an exposed surface of the semiconductor chip, so as to eliminate a popcorn effect and assure the quality of the semiconductor package. Furthermore, the invention with the partially exposed semiconductor chip makes heat generated by the semiconductor chip directly dissipated to the atmosphere so as to effectively increase the heat dissipating efficiency, and thus performance and lifetime of the semiconductor package can be maintained. In addition, the heat dissipating element used in the invention can be fabricated in a costly effective manner, so as to reduce the fabrication cost for the semiconductor package.

In accordance with the foregoing and other objectives, the present invention proposes a TCDBGA (thin cavity down ball grid array) semiconductor package, comprising: a heat dissipating element, a substrate, a semiconductor chip, a plurality of first conductive elements, a plurality of second conductive elements and an encapsulant. The heat dissipating element has a penetrating opening with an area A formed at the center thereof, a chip bonding region formed around the opening on a surface of the heat dissipating element for sufficiently encompassing the opening, while the chip bonding region having an area A′ of approximately the same size as a semiconductor chip, and a substrate attaching region positioned around the chip bonding region. Further, the substrate has a top surface and a conductive-trace surface, in which on the conductive-trace surface there are formed a plurality of conductive tram and bonding pads, and at the center of the substrate there is formed a penetrating opening with an area larger than the area A′ of the chip bonding region, while the substrate attaching region of the heat dissipating element is attached to the top surface of the substrate by a conventional attaching technology in a manner that the opening of the heat dissipating element is positioned above the opening of the substrate. Moreover, the semiconductor chip has an active surface with a plurality of electronic circuits and electronic elements formed thereon, and an inactive surface attached to the chip bonding region of the heat dissipating element by a thermally conductive adhesive for covering the opening of the heat dissipating element. Furthermore, The first conductive elements (gold wires) are used for electrically connecting the semiconductor chip to the conductive traces of the substrate, whereas the second conductive elements (solder bumps, including solder balls) provide electrical connection of the substrate to external devices. Finally, the encapsulant is formed to encapsulate the semiconductor chip, the first conductive elements, pat of the heat dissipating element and part of the substrate.

The semiconductor package of the invention is constructed in a manner that the semiconductor chip only has its edge portion attached to the chip bonding region of the heat dissipating element by the thermally conductive adhesive, which significantly reduces the contact area between the heat dissipating element and the semiconductor chip, as compared with the semiconductor chip entirely attached to the heat sink in the prior art. This therefore reduces a thermal stress resulted from difference in coefficient of thermal expansion (CTE) between the heat dissipating element and the semiconductor chip, and further helps prevent the occurrence of cracking for the semiconductor chip during a temperature cycle, warpage of the substrate which degrades the planarity and bonding quality of the semiconductor package, as well as delamination of inner elements in the semiconductor package.

Furthermore, in the semiconductor package of the invention, since the semiconductor chip has a surface partially exposed to the atmosphere, moisture enclosed in the encapsulated semiconductor package can escape to the atmosphere via the exposed surface of the semiconductor chip, so as to prevent a popcorn effect from occurring in a reflow process, and thus the quality of the packaged product can be assured. In addition, heat generated by the semiconductor chip can be effectively dissipated through the heat dissipating element and the expos surface of the semiconductor chip, which further improves the heat dissipating efficiency as well as maintains the performance and lifetime of the semiconductor chip.

In another embodiment of the invention, a lead-frame device is employed instead of the foregoing ball grid array structure, wherein a semiconductor chip is attached to a heat dissipating element in the same manner as that in the TCDBGA semiconductor package, and thus the same improvements rendered by the above embodiment can be achieved herein.

### BRIEF DESCRIPTION OF THE DRAWINGS

The present invention can be more fully understood by reading the following detailed description of the preferred embodiments, with reference made to the accompanying drawings wherein:

FIG. 1 (PRIOR ART) is a sectional view of a semiconductor package with a heat sink,

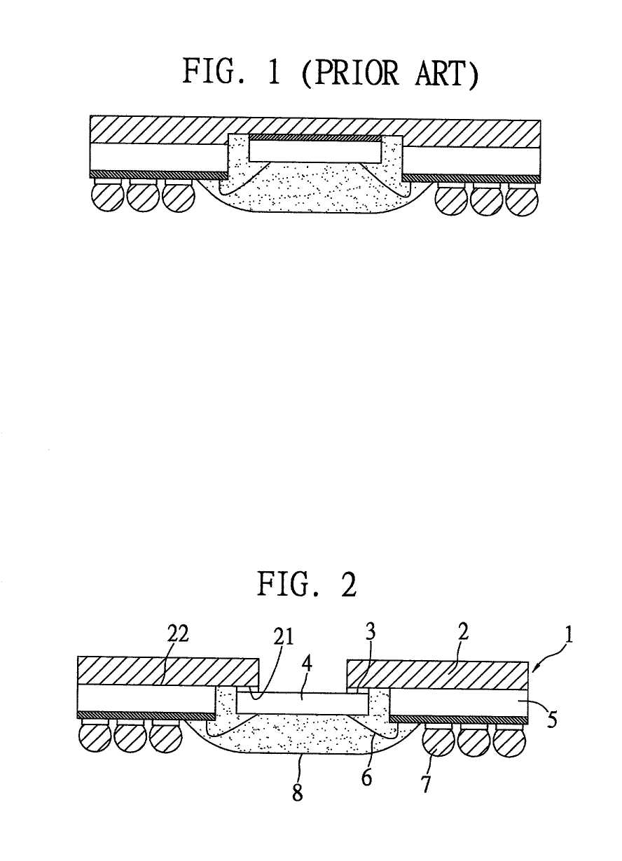

FIG. 2 is a sectional view of a first preferred embodiment of the semiconductor package of the invention,

FIGS. 3A-3E are schematic diagrams showing the steps involved in a fabricating process for the semiconductor package of the invention; and

FIG. 4 is a sectional view of a second preferred embodiment of the semiconductor package of the present invention.

### DETAILED DESCRIPTION OF PREFERRED EMBODIMENT

### First Preferred Embodiment (TCDBGA Semiconductor Package)

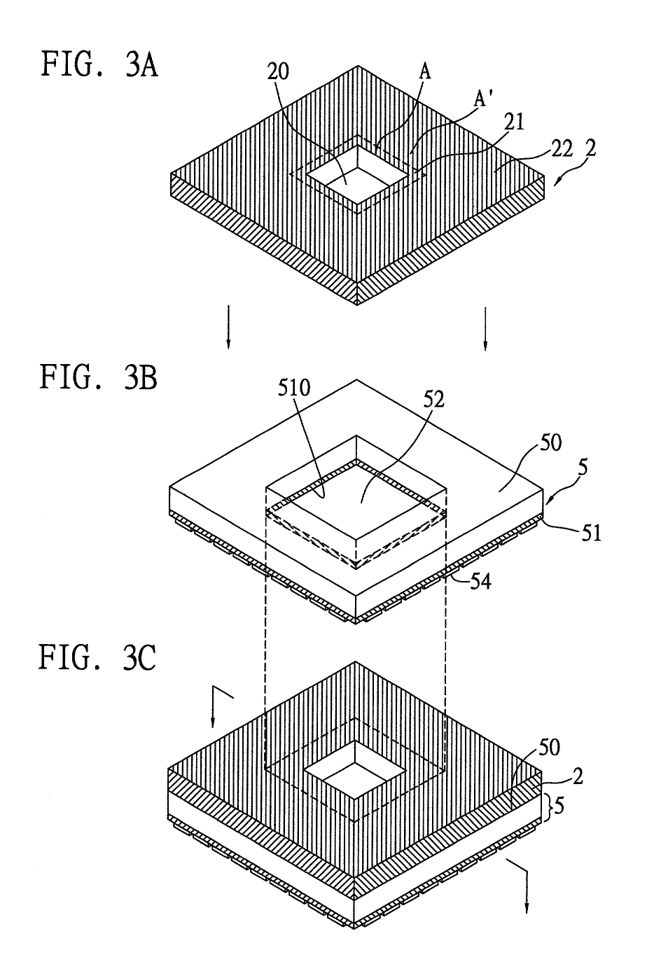

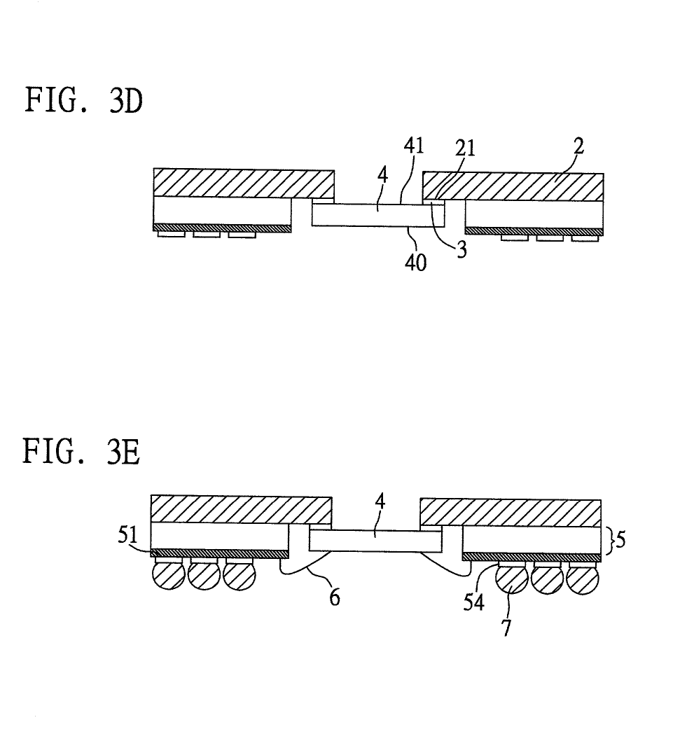

As shown in FIG. 2, the TDCBGA semiconductor package 1 of the first embodiment includes a heat sink 2 having a chip bonding region 21 formed at the enter thereof and a substrate attaching region 22 positioned around the chip bonding region 21; a semiconductor chip 4 disposed to the chip bonding region 20 by a thermally conductive adhesive 3; and a substrate 5 attached to the substrate attaching region 22 of the heat sink 2; a plurality of gold wires 6 for electrically connecting the semiconductor chip 4 to the substrate 5; a plurality of solder bumps 7 for electrically connecting the substrate 5 to external devices; and a encapsulant 8 for encapsulating the semiconductor chip 4, the gold wires 6, part of the substrate 5 and part of the heat sink 2. The fabricating process for the semiconductor package 1 is detailed in FIGS. 3A-3E as follows

Referring first to FIG. 3A, a heat sink 2 is prepared, which has a penetrating opening 20 formed with an area A at the center thereof, a chip bonding region 21 formed around the opening 20 on a surface of the heat sink 2 for sufficiently encompassing the opening area A, while the chip boning region 21 having an area A′ of approximately the same size as a semiconductor chip 4, and a substrate attaching region 22 positioned around the chip bonding region 21.

Referring next to FIG. 3B, a substrate 5 having a top surface 50 and a conductive-trace surface 51 is provided. At the center of the substrate 5 there is formed a penetrating opening 52 with an area lager than the area A′ of the chip bonding region 21. On the conductive-trace surface 51 close to the opening 52, there is formed a wire bonding region 510 for disposing a plurality of bonding pads (not shown) and conductive traces (not shown) thereon, while on the conductive-trace surface 51 distant from the opening 52, there are formed a plurality solder pas 54 for implanting a plurality of solder bumps 7 so as to electrical connect the substrate 5 to external devices.

Referring further to FIG. 3C, the heat sink 2 is firmly attached to the top surface 50 of the substrate 5 by an attaching technology, allowing the opening 20 of the heat sink 2 to be positioned correspondingly above the opening 52 of the substrate 5. Since the attaching technology is conventional, it is not further detailed herein The substrate 5 can be made of an elastic or non-elastic material such as epoxy resin, BT (bismaleimidetriazine) resin, FR4 substrate, polyimide resin, ceramics or glass material

Referring further to FIG. 3D, a semiconductor chip 4 attached to the combined structure of the heat sink and the substrate is illustrated. As shown in the drawing, the semiconductor chip 4 has an active surface 40 for disposing a plurality of electronic circuits and electronic elements thereon for forming a plurality of bonding pads (not shown) and an inactive surface 41 thereon. Then the inactive surface 41 of the semiconductor chip 4 is firmly attached to the chip bonding region 21 of the heat sink 2 by a thermally conductive adhesive 3.

Moreover, as the semiconductor chip 4 merely has its edge portion attached to the heat sink 2 by the thermally conductive adhesive 3, part of the inactive surface 41 of the semiconductor chip 4 is exposed directly to the atmosphere. Accordingly, heat generated by the semiconductor chip 4 can be directly dissipated through the semiconductor chip 4 itself so as to effectively improve the heat dissipating efficiency and maintain the performance and lifetime of the semiconductor chip 4. Furthermore, the reduced contact area between the semiconductor chip, 4 and the heat sink 2 correspondingly reduces a thermal stress resulted from difference in coefficient of thermal expansion therebetween, and therefore cracking for the semiconductor chip and delamination as well as warpage can be prevented, so as to greatly improve the quality of the packaged product.

Referring finally to FIG. 3E, the semiconductor chip 4 is electrically connected to the bonding pads (not shown) formed on the conductive-trace surface 5 by a plurality of gold wires 6. Then an encapsulant 8 is formed to encapsulate the semiconductor chip 47 the gold wires 6, part of the substrate 5 and part of the heat sink 2. Finally, with the use of a conventional implantation process, a plurality of solder bumps 7 (including solder balls) are implanted on the solder pads 54 of the conductive-trace surface 51 for electrical connecting the substrate 5 to external devices, so as to complete the fabrication for the TCDBGA semiconductor package 1 as shown in FIG. 2.

### Second Preferred Embodiment (TQFP Semiconductor Package)

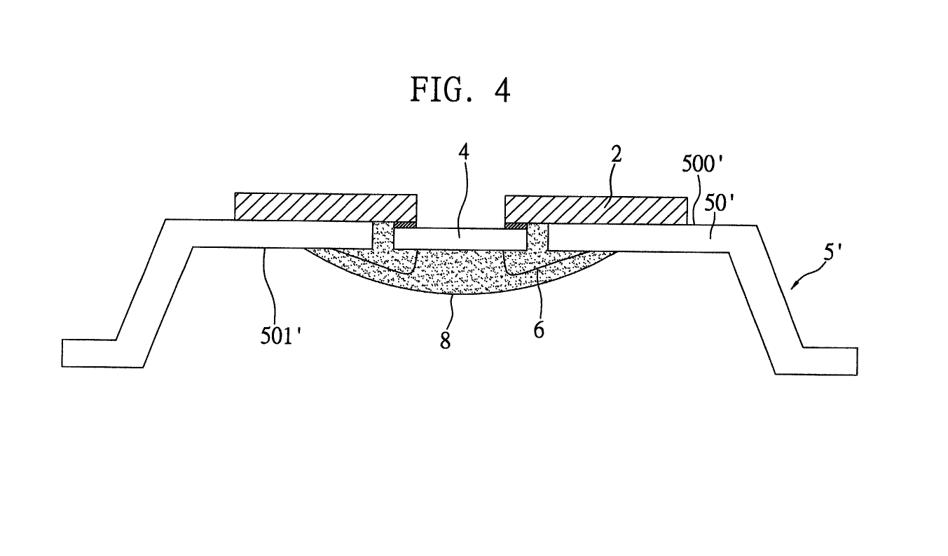

Illustrated in FIG. 4 is a TQFP (thin quad flat package) semiconductor package in the second embodiment of the invention. The TQFP semiconductor package is fabricated in a similar manner to the semiconductor package in the first embodiment, and thus the fabricating process is not further detailed herein. Further in the drawing, elements of the TQFP semiconductor package same as those of the semiconductor package in the first embodiment are designated by the same reference numerals.

As shown in FIG. 4, the TQFP semiconductor package differs from the semiconductor package in the first embodiment only in that a lead frame 5′ is employed in the TQFP semiconductor package. The lead frame 5′ has a top surface 500′ and opposing bottom surface 501′, and is formed with a plurality of leads 50′ but no die pad. The heat sink 2 is directly attached to the top surfaces 500′ of the leads 50′, whereas a plurality of inner leads 51′ formed on the b m surface 501′ are used for electrically connecting the semiconductor chip 4 to the lead frame 5′ by the gold wires 6. Moreover, the leads 50′ made of metal are used in place of the solder bumps 7 for electrically connecting the lead frame 5′ to external devices. Further as the semiconductor chip 4 is attached to the heat sink 2 in the same manner as that in the first embodiment, the same improvements rendered by the TCDBGA semiconductor package can be achieved in the TQFP semiconductor package.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A semiconductor package with a heat dissipating element, comprising:
a heat dissipating element having a penetrating opening, a chip bonding region formed at a periphery of the penetrating opening for completely encompassing area of the penetrating opening, and a substrate attaching region formed at a periphery of the chip bonding region,
a substrate attached to the substrate attaching region of the heat dissipating element, and having a top surface and a conductive-trace surface, wherein a penetrating opening larger than area of the chip bond region is formed at a position of the substrate corresponding to the chip bonding region of the heat dissipating element,
a semiconductor chip mounted to the chit) bonding region for coveting the penetrating opening of the heat dissipating element,
a plurality of first conductive elements for electrically connecting the semiconductor chip to the substrate;
a plurality of second conductive elements formed on the conductive-trace surface of the substrate for electrically connecting the substrate to external devices, and
an encapsulant for encapsulating the semiconductor chip and the first conductive elements.

2. The semiconductor package of claim 1, wherein the semiconductor package is a TCDBGA (thin cavity down ball grid array) semiconductor package.

3. The semiconductor package of claim 1, wherein the chip bonding region completely encompassing the area of the penetrating opening, is of a size approximately the same as that of the semiconductor chip.

4. The semiconductor package of claim 1, wherein said heat dissipating element is a heat sink.

5. The semiconductor package of claim 1, wherein the penetrating opening of the heat dissipating element is positioned above the opening of the substrate.

6. The semiconductor package of claim 1, wherein the semiconductor chip has an active surface and an inactive surface.

7. The semiconductor package of claim 6, wherein the inactive surface of the semiconductor chip is attached to the chip bonding region by a thermally conductive adhesive.

8. The semiconductor package of claim 1, wherein on the conductive-trace surface close to the opening of the substrate there is formed a wire bonding region for disposing a plurality of conductive traces and a plurality of bonding pads thereon.

9. The semiconductor package of claim 1, wherein on the conductive-trace surface distant from the opening of the substrate there are formed a plurality of solder pads for implanting the second conductive elements thereon.

10. The semiconductor package of claim 1, wherein the first conductive elements are gold wires.

11. The semiconductor package of claim 1, wherein the second conductive elements are solder bumps, including solder balls.

12. A semiconductor package with a heat dissipating element, comprising:
a heat dissipating element having a penetrating opening and a chip bonding region formed at a periphery of the penetrating opening for completely encompassing area of the penetrating opening;
a lead frame having a plurality of leads for attaching the lead frame to the heat dissipating element by the leads,
a semiconductor chip mounted to the chip bonding region for covering the penetrating opening of the heat dissipating element;
a plurality of first conductive elements for electrically connecting the semiconductor chip to the leads, and
an encapsulant for encapsulating the semiconductor chip and the first conductive elements.

13. The semiconductor package of claim 12, wherein the chip bonding region completely encompassing the area of the penetrating opening is of a size approximately the same as that of the semiconductor chip.

14. The semiconductor package of claim 12, wherein the leads have a top surface and an opposing bottom surface.

15. The semiconductor package of claim 14, wherein the heat dissipating element is attached to the top surface of the leads.

16. The semiconductor package of claim 12, wherein the semiconductor chit has an active surface and an inactive surface.

17. The semiconductor package of claim 16, wherein the inactive surface of the semiconductor chip is attached to the chip bonding region by a thermally conductive adhesive.

18. The semiconductor package of claim 12, wherein the heat dissipating element is a heat sink.

19. The semiconductor package of claim 12, wherein the first conductive elements are gold wires.
